(19) United States
(12) Patent Application Publication
(10) Pub. No.: US 2006/0076639 A1
(43) Pub. Date: Apr. 13, 2006

(54) Schottky diodes and methods of making the same

(76) Inventors: William J. Lypen, Fort Collins, CO (US); Rick Snyder, Fort Collins, CO (US); David W. Bigelow, Fort Collins, CO (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 10/964,163

(22) Filed: Oct. 13, 2004

(51) Int. Cl. H01L 31/07; H01L 21/28

(52) U.S. Cl. 257/471; 438/570; 257/472; 257/473; 257/481

(57) ABSTRACT

In one aspect, a Schottky diode includes a semiconductor material, and a metal material forming a Schottky barrier junction with the semiconductor material, wherein a cavity having a lateral dimension of at least 200 nm is adjacent to the Schottky barrier junction. In another aspect, a Schottky diode includes a semiconductor surface, a dielectric structure, and a contact structure. The dielectric structure defines an opening to the semiconductor surface. The contact structure extends through the opening in the dielectric structure to form a Schottky barrier junction with the semiconductor surface. The contact structure comprises a bonding pad overlying the Schottky barrier junction and at least a portion of the dielectric structure and being electrically connected to the Schottky barrier junction.

### BACKGROUND

A Schottky diode is formed at the junction of a metal and a semiconductor material that is characterized by a surface charge in the metal and an equal but opposite space charge in the semiconductor at thermal equilibrium. The charge distribution of a Schottky diode is similar to that of a p-n junction diode with a corresponding similar field distribution. The primary electric current in a Schottky diode, however, is majority carrier current, whereas the primary electric current in a p-n junction diode is minority carrier current. The dominant transport mechanism in a Schottky diode is thermionic emission of majority carriers from the semiconductor material to the metal. A Schottky diode is characterized by a rectifying current-voltage relationship with a high-resistance reverse bias direction and a relatively low-resistance forward bias direction.

For high-speed applications, it is desirable for a Schottky diode to have a fast switch-off time, a low series resistance, a low capacitance, and a low reverse-bias leakage current.

The switch-off time of a Schottky diode is increased by reducing the series resistance and reducing the capacitance. The series resistance of a Schottky diode typically is determined by the doping level in the semiconductor material. The Schottky diode capacitance typically is reduced by minimizing the size of the junction area between the metal and the semiconductor material and by placing the Schottky diode far away from large metallic structures, such as bonding pads and the like.

A variety of different approaches for reducing the reverse bias leakage currents in a Schottky diode have been proposed. In one approach, a contact opening through an insulating layer and a thermal oxide layer is overetched to form a shallow trench in an underlying silicon substrate. A metal layer is deposited within the shallow trench and sintered to form a silicide layer contacting the silicon substrate at the bottom and sidewalls of the shallow trench. A barrier layer is formed over the silicide layer and a second metal layer is deposited over the barrier layer to complete the Schottky diode.

### SUMMARY

In one aspect of the invention, a Schottky diode includes a semiconductor material, and a metal material forming a Schottky barrier junction with the semiconductor material, wherein a cavity having a lateral dimension of at least 200 nm (nanometers) is adjacent to the Schottky barrier junction.

In another aspect, the invention features a method of forming a Schottky diode. In accordance with this inventive method, a semiconductor surface is provided. A dielectric structure defining an opening to the semiconductor surface is formed. A contact structure extending through the opening in the dielectric structure is formed to form a Schottky barrier junction with the semiconductor surface, wherein at the semiconductor surface at least a portion of the Schottky barrier junction is spaced apart from the dielectric structure by a lateral distance of at least 200 nm.

In another aspect of the invention, a Schottky diode includes a semiconductor surface, a dielectric structure, and a contact structure. The dielectric structure defines an opening to the semiconductor surface. The contact structure extends through the opening in the dielectric structure to form a Schottky barrier junction with the semiconductor surface. The contact structure comprises a bonding pad structure that overlies the Schottky barrier junction and at least a portion of the dielectric structure and is electrically connected to the Schottky barrier junction.

Other features and advantages of the invention will become apparent from the following description, including the drawings and the claims.

### DESCRIPTION OF DRAWINGS

FIG. 1A is a diagrammatic cross-sectional view of a prior art Schottky diode.

FIG. 1B is an enlarged view of the Schottky barrier region of an implementation of the prior art Schottky diode shown in FIG. 1A.

FIG. 1C is an enlarged view of the Schottky barrier region of another implementation of the prior art Schottky diode shown in FIG. 1A.

FIG. 2 is a diagrammatic view of an embodiment of a Schottky diode.

FIG. 3A is an energy band diagram of the Schottky diode embodiment of FIG. 2 in thermal equilibrium.

FIG. 3B is an energy band diagram of the Schottky diode embodiment of FIG. 2 under forward bias.

FIG. 3C is an energy band diagram of the Schottky diode embodiment of FIG. 2 under reverse bias.

FIG. 4A is a cross-sectional side view of an implementation of the Schottky diode embodiment of FIG. 2.

FIG. 4B is a diagrammatic top view of the Schottky diode implementation of FIG. 4A.

FIG. 5A is a graph of forward current plotted as a function of forward voltage for an exemplary implementation of the Schottky diode implementation shown in FIGS. 4A and 4B at 25° C.

FIG. 5B is a graph of reverse current plotted as a function of reverse voltage for an exemplary implementation of the Schottky diode implementation shown in FIGS. 4A and 4B at 25° C.

FIG. 6 is a flow diagram of an embodiment of a method of making the Schottky diode implementation shown in FIGS. 4A and 4B.

FIG. 7 is a cross-sectional side view of another implementation of the Schottky diode embodiment of FIG. 2.

### DETAILED DESCRIPTION

In the following description, like reference numbers are used to identify like elements. Furthermore, the drawings are intended to illustrate major features of exemplary embodiments in a diagrammatic manner. The drawings are not intended to depict every feature of actual embodiments nor relative dimensions of the depicted elements, and are not drawn to scale.

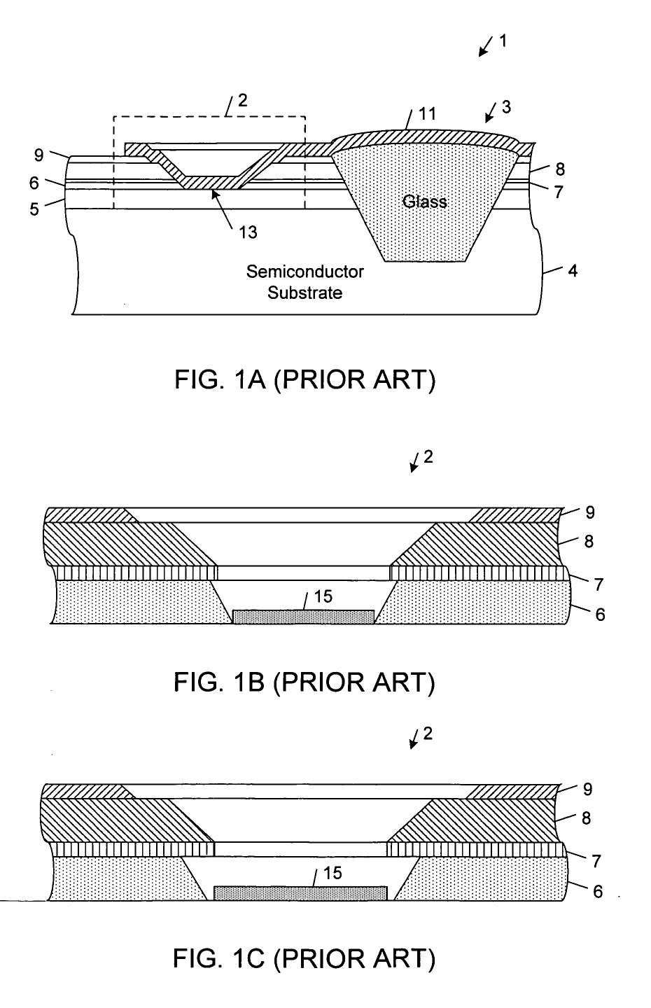

FIG. 1 shows a prior art Schottky diode 1 that includes a Schottky barrier region 2 and a bonding pad region 3, which is spaced apart from the Schottky barrier region 2. The Schottky diode 1 includes a semiconductor substrate 4, a semiconductor epitaxial layer 5, a 160 nm thick oxide layer 6, a 180 nm thick nitride layer 7, a 1000 nm thick low-temperature oxide (LTO) film 8, and a 60 nm thick top nitride layer 9. A metallization layer 11 electrically connects the bonding pad region 3 to the Schottky barrier region 2.

Referring to FIGS. 1B and 1C, an oxide etching process is used to etch through the oxide layer 6 to expose the surface of the epitaxial layer 5 where the Schottky barrier junction 13 is formed. The nitride layer 7 serves as a mask for the oxide etching process. During the oxide etching process, some of the oxide layer material is removed from under the nitride layer 7, as shown in FIGS. 1B and 1C. The degree to which the oxide layer material is removed from under the nitride layer 7 is not a parameter that is specified in the fabrication process of Schottky diode 1. Due to process variations and other factors, the degree to which the oxide layer material is removed from under the nitride layer 7 varies from run-to-run and from batch-to-batch. As a result, in some devices, the Schottky metal layer 15, which forms the Schottky barrier junction 13, is observed to be in contact with the etched sidewalls of the oxide layer 6, as shown in FIG. 1B. In other devices, the Schottky metal layer 15 is observed to be spaced-apart from the etched sidewalls of the oxide layer 6. The spacing between the Schottky metal layer 15 and the sidewalls of the oxide layer 6 have been observed to vary from 0 nm to about 180 nm.

The Schottky diode embodiments described in detail below incorporate Schottky barrier junctions with respective portions that are laterally spaced apart from dielectric material at the semiconductor surface where the junction is formed by a distance of at least 200 nm. As used herein, the terms “lateral” and “laterally” relate to directions and dimensions that are substantially parallel to the semiconductor surface where the Schottky barrier junction is formed. The spacing between the Schottky barrier junctions and the dielectric material has been observed to unexpectedly improve the performance of these embodiments by reducing the reverse bias leakage currents exhibited by the Schottky barrier junctions. In addition, these embodiments also incorporate novel dielectric structures, which enable bonding pads to be disposed over the Schottky barrier junctions. In this way, the dielectric structures obviate the placement of the bonding pads far away from the Schottky barrier junctions and thereby allow a significant reduction in the amount of die area needed to implement a the Schottky diode.

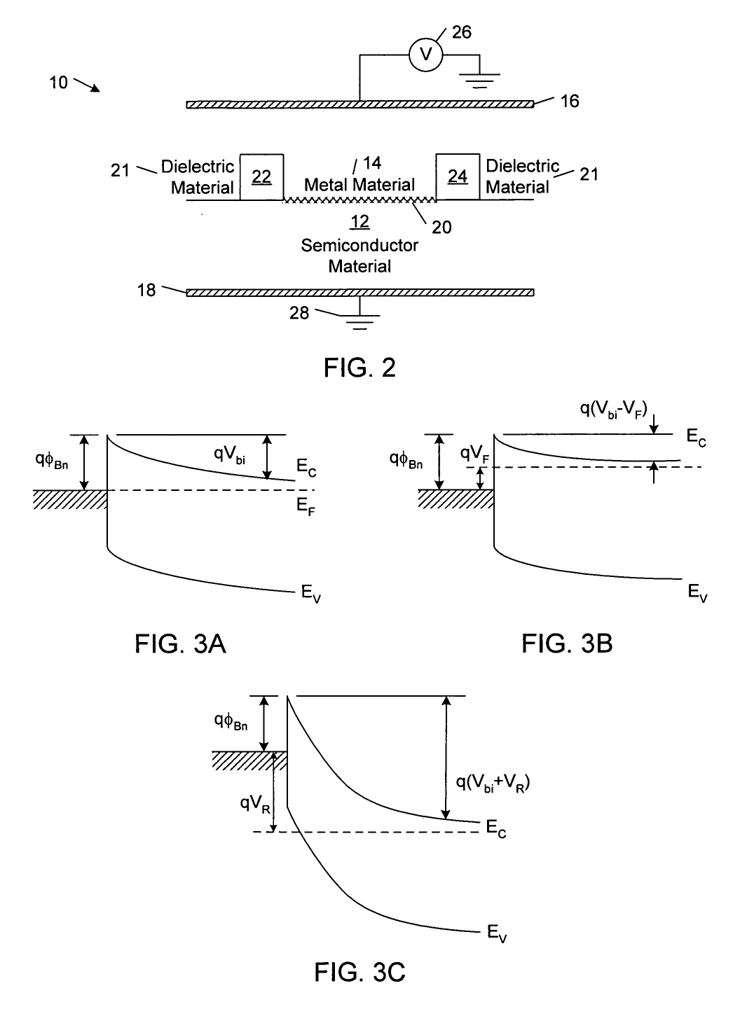

FIG. 2 shows an embodiment of a Schottky diode 10 that includes a semiconductor material 12, a metal material 14, a first electrode 16, and a second electrode 18.

The semiconductor material 12 may be any type of semiconductor material, including any type of elemental semiconductor material (e.g., silicon or germanium) or compound semiconductor material (e.g., a III-V semiconductor material, such as gallium arsenide and indium phosphide, or a II-VI semiconductor material, such as zinc selenide and cadmium sulphide). The semiconductor material may be an epitaxial semiconductor film or it may be a bulk semiconductor material. The semiconductor material 12 may be doped n-type or p-type. In general, the doping level should be below the level at which the junction 20 becomes ohmic. An exemplary doping level range for the semiconductor material 12 is 10¹⁵-10¹⁷ atoms per cubic centimeter (cm³).

The metal material 14 forms a Schottky barrier junction 20 with the semiconductor material 12. The metal material 14 may by any type of metal or metal alloy that forms a Schottky barrier junction 20 with the semiconductor material 12. The metal or metal alloy is referred to herein as a Schottky metal. Exemplary Schottky metals include metals and alloys formed from one or more of the following: platinum, hafnium, cobalt, tantalum, palladium, and titanium.

At least a portion of the Schottky barrier junction 20 is spaced apart from dielectric material 21 at the semiconductor surface where junction 20 is formed by a lateral distance of at least 200 nm. In particular, one or more cavities 22, 24, which have lateral dimensions of at least 200 nm, are juxtaposed with the Schottky barrier junction 20. The cavities 22, 24 may be part of a single cavity-defining structure or they may be discrete cavities separated from one another by regions of material. Each cavity constitutes an unfilled space within a mass of material that encloses the cavity. The enclosing mass of material may have a uniform composition or a nonuniform composition. In the illustrated embodiment, the cavities 22, 24 are disposed at the periphery of the Schottky barrier junction. In some implementations, the cavities 22, 24 are part of a single cavity structure that surrounds the Schottky barrier junction 20. In one of these implementations, the surrounding cavity structure forms an annular ring around the Schottky barrier junction 20. In some implementations, the metal material 14 that forms the Schottky barrier junction 20 also forms at least one wall of each cavity such that the Schottky barrier junction extends right up to the cavities 22, 24. In other implementations, one or more of the cavities 22, 24 are spaced apart from the Schottky barrier junction 20 by a lateral distance within a range of about 0.1 nm to about 100 nm. In some implementations, at least some of the non-cavity space between the metal material 14 and the dielectric material 21 is filled with a non-dielectric, non-Schottky-barrier-forming material, such as a non-Schottky metal or metal alloy.

In the illustrated embodiment, the first electrode 16 is connected to a lo voltage source 26 and the second electrode 18 is connected to a ground potential 28. In other embodiments, the first and second electrodes 16, 18 may be connected to different voltage levels. The voltage level (V) applied across the Schottky diode 10 determines the current level that flows through the device.

Under typical operating conditions, the Schottky diode 10 exhibits a rectifying current-voltage relationship: under forward bias, a forward current flows through the Schottky diode 10; and under reverse bias, only a small reverse bias leakage current flows through the device. When the semiconductor material 12 is doped n-type, a positive voltage (V>0) drives the Schottky diode 10 into forward bias and a negative voltage (V<0) drives the Schottky diode 10 into reverse bias. In contrast, when the semiconductor material 12 is doped p-type, a negative voltage (V<0) drives the Schottky diode 10 into forward bias and a positive voltage (V>0) drives the Schottky diode 10 into reverse bias.

In the illustrated embodiment, the first and second electrodes 16, 18 are positioned to generate electric fields that drive electric currents through the semiconductor material roughly orthogonally with respect to the Schottky barrier junction 20. In other embodiments, the first and second electrodes 16, 18 may be located at other positions. For example, in one embodiment, the first and second electrodes 16, 18 are located on the same side of the Schottky barrier junction and generate electric fields that drive electric currents through the semiconductor material roughly parallel to the Schottky barrier junction.

FIG. 3A shows an exemplary energy band diagram for an implementation of Schottky diode 10 at thermal equilibrium. In this implementation, the semiconductor material 12 is doped n-type. FIG. 3B shows an exemplary band diagram for the same implementation of Schottky diode 10 under forward bias (VF). FIG. 3C shows an exemplary band diagram for the same implementation of Schottky diode 10 under reverse bias (VR).

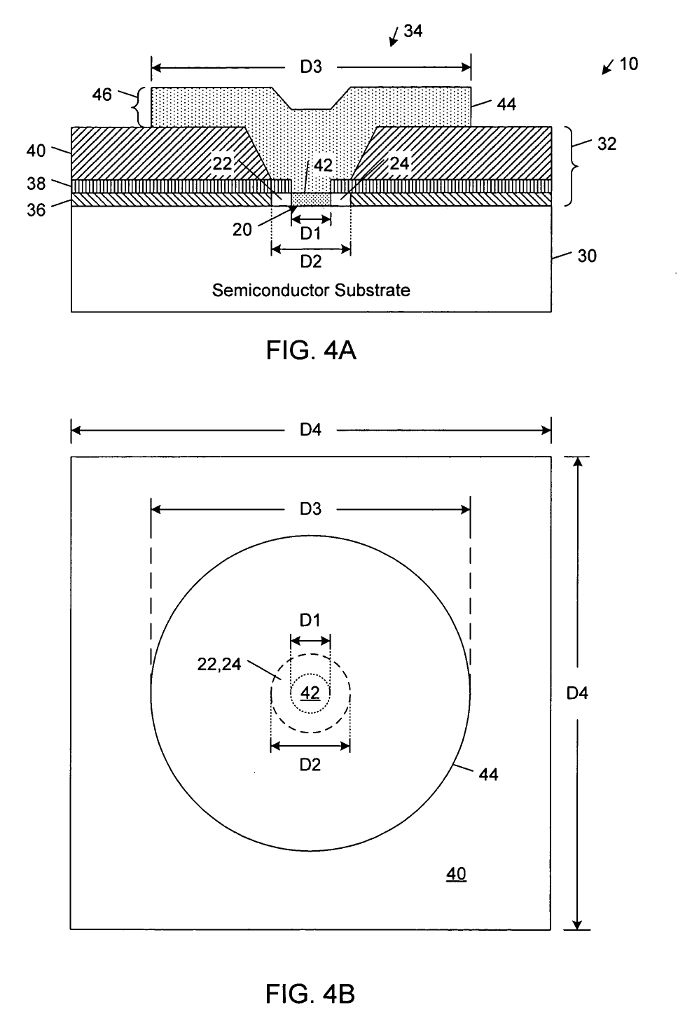

FIGS. 4A and 4B show an implementation of the Schottky diode 10 that includes a semiconductor substrate 30, a dielectric structure 32 that is formed on the semiconductor substrate 30, and a contact structure 34 that is formed on the semiconductor substrate 30. The substrate 30 may be an epitaxial or bulk semiconductor material, as describe above. In one implementation, the substrate 30 includes a bulk semiconductor and an overlying epitaxial semiconductor film formed on the bulk semiconductor.

The dielectric structure 32 includes a stack of a first dielectric layer 36, a second dielectric layer 38, and a third dielectric layer 40. The first dielectric layer 36 forms sidewalls of the cavities 22, 24. The second dielectric layer 38 forms a projection that overhangs the semiconductor substrate 30 and forms top walls of the cavities 22, 24. The third dielectric layer 40 defines a tapered top portion of an opening that extends through the dielectric stack to the surface of the semiconductor substrate 30. The dielectric layers 36-40 may be formed of any type of dielectric material. In some implementations, the first dielectric layer 36 and the second dielectric layer 38 are formed of materials that are selectively etchable with respect to each other. This feature allows the cavities 22, 24 to be defined by selective removal of a portion of the first dielectric layer 36 under the second dielectric layer 38. In the illustrated embodiment, the third dielectric layer 40 is formed of a material that can be etched anisotropically to form the tapered top portion of the opening in the dielectric structure 32.

The contact structure 34 includes a Schottky metal layer 42 and an overlying top metallization 44. The Schottky metal layer 42 forms the Schottky barrier junction 20 with the semiconductor substrate 30. The overlying top metallization 44 is electrically connected to the Schottky metal layer 42 and is disposed over the Schottky barrier junction 20 and at least a portion of the dielectric structure 32. The top metallization 44 includes a bonding pad structure 46 that is configured to be wirebonded to, for example, an external electronic component. In some implementations, the top metallization 44 intrudes into and at least partially fills the space between the Schottky metal layer 42 and the sidewalls of the first dielectric layer 36. In these implementations, the reduced leakage current effects of the spacing between the Schottky metal layer 42 and the dielectric layer 36 are still observed.

As shown in FIG. 4B, in the illustrated embodiment, the cavities 22, 24 are part of a single cavity structure that forms an annular ring around the Schottky barrier junction 20 and has an inner diameter D1 and an outer diameter D2. To achieve improved reverse bias leakage performance, it has been observed that, at the semiconductor surface where the Schottky barrier junction 20 is formed, the spacing between the Schottky metal layer 42 and the sidewalls of the first dielectric layer 36 should be at least 200 nm. In some implementations, the difference D2-D1 preferably ranges from 400 nm to 1200 nm, and more preferably ranges from 480 nm to 800 nm.

In one exemplary implementation, the substrate 30 is formed of a bulk silicon chip with an overlying epitaxial silicon film. The first dielectric layer 36 is formed of a 120 nm silicon oxide layer, the second dielectric layer 38 is formed of an 180 nm silicon nitride layer, and the third dielectric layer 40 is formed of a 1.5 micrometer (μm) silica film, such as a film formed by a tetraethylorthosilicate (TEOS) deposition. The Schottky metal layer 42 is formed of a 100 nm titanium film and the top metallization includes a bottom layer formed of a 150 nm tungsten/nickel alloy film and a top layer formed of a 700 nm gold film. In this implementation, the lateral dimensions are as follows: D1 is 8 μm; D2 is 9 μm; D3 is 50 μm; and D4 is 200 μm.

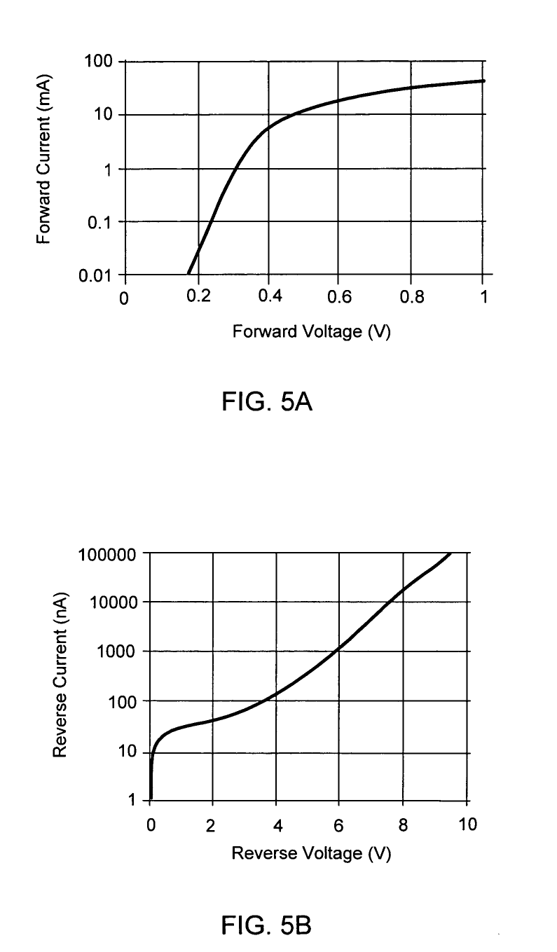

FIGS. 5A and 5B respectively show a graph of forward current plotted as a function of forward voltage and a graph of reverse current plotted as a function of reverse voltage for an exemplary implementation of the Schottky diode implementation described in the preceding paragraph at 25° C.

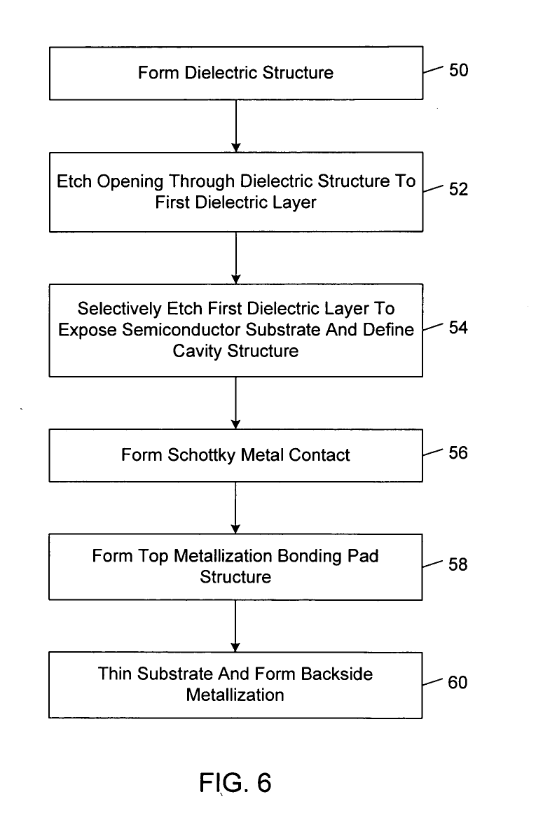

FIG. 6 shows an embodiment of a method of making the implementation of the Schottky diode 10 shown in FIGS. 5A and 5B.

In accordance with this method, the dielectric structure 32 is formed (block 50). This process involves growing or depositing the first, second and third dielectric layers 36, 38, 40.

After the dielectric structure 32 has been formed (block 50), an opening is etched through the dielectric structure 32 to the first dielectric layer 36 (block 52). In this process, contact mask initially is deposited on the third dielectric layer 40 to define the contact opening. With respect to the exemplary implementation described above in which the dielectric structure is formed of a stack of a TEOS dielectric, silicon nitride, and silicon oxide, the opening is etched through the TEOS dielectric layer 40 using an isotropic dry oxide etching process, such as reactive ion etching, and a dry nitride etching process is used to etch through the silicon nitride layer 38.

Next, the first dielectric layer 36 is selectively etched to expose the semiconductor substrate 30 and to define the cavity structure 22, 24 (block 54). The selective etch preferentially etches the underlying dielectric layer 38 relative to the overlying dielectric layer 38. In this way, the selective etching process removes a portion of the first dielectric layer 36 under the second dielectric layer 38, which projects over the resulting cavity areas. With respect to the exemplary implementation described above in which the dielectric structure is formed of a stack of a TEOS dielectric, silicon nitride, and silicon oxide, the first silicon oxide layer 36 is etched using a wet oxide etching process. During this process, the selective etching process may concurrently anisotropically etch the third dielectric layer 40 to form the tapered sidewalls at the top portion of the opening.

The Schottky metal contact 42 is formed by a front metal deposition process that involves depositing a Schottky metal layer through the opening onto the exposed surface of the semiconductor substrate 30 (block 56). A contact metal mask is deposited on the Schottky metal layer and the Schottky metal contact region is defined lithographically. Non-contact regions of the Schottky metal layer are removed using a contact metal etching process. The residual contact metal mask also is removed.

The top metallization 44 is formed by depositing the top metallization layer (or layers) into the opening over the Schottky metal layer 42 and over at least a portion of the dielectric structure 32 (block 58). A pad metal mask is deposited on the top metallization and the pad metal contact region is defined lithographically. Non-contact regions of the top metallization are removed using a pad metal etching process. The residual pad metal mask also is removed.

The semiconductor substrate 30 may be thinned and a backside metallization may be deposited on the side of the semiconductor substrate 30 to complete the Schottky diode 10 (block 60).

Other embodiments are within the scope of the claims.

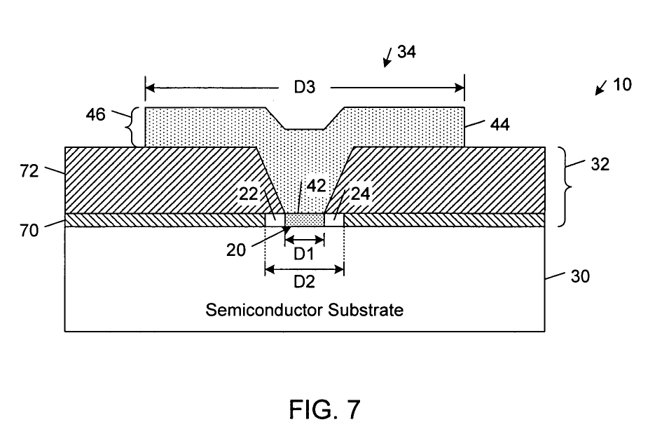

For example, FIG. 7 shows an implementation of the Schottky diode 10 that corresponds to the implementation shown in FIGS. 4A and 4B, except the dielectric structure 68 is formed from only two dielectric layers 70, 72 whereas the dielectric structure 32 (FIG. 4A) is formed from three dielectric layers 36, 38, 40. In this implementation 66, the first dielectric layer 70 forms sidewalls of the cavities 22, 24. The second dielectric layer 72 forms a projection that overhangs the semiconductor substrate 30 and forms top walls of the cavities 22, 24 and defines a tapered top portion of an opening that extends through the dielectric structure 68 to the surface of the semiconductor substrate 30. The dielectric layers 70, 72 may be formed of any type of dielectric material. In some implementations, the first dielectric layer 70 and the second dielectric layer 72 are formed of materials that are selectively etchable with respect to each other. This feature allows the cavities 22, 24 to be defined by selective removal of a portion of the first dielectric layer 70 under the second dielectric layer 72. In the illustrated embodiment, the second dielectric layer 72 is formed of a material that can be etched anisotropically to form the tapered top portion of the opening in the dielectric structure 68.

What is claimed is:

1. A Schottky diode, comprising:
a semiconductor material; and
a metal material forming a Schottky barrier junction with the semiconductor material, wherein a cavity having a lateral dimension of at least 200 nm is adjacent to the Schottky barrier junction.

2. The Schottky diode of claim 1, wherein the cavity is disposed at the periphery of the Schottky barrier junction.

3. The Schottky diode of claim 2, wherein the cavity surrounds the Schottky barrier junction.

4. The Schottky diode of claim 3, wherein the cavity forms an annular ring around the Schottky barrier junction.

5. The Schottky diode of claim 1, further comprising a dielectric structure defining an opening to the semiconductor material, and a contact structure electrically connected to the metal material through the opening.

6. The Schottky diode of claim 5, wherein the dielectric structure includes a projection overhanging the semiconductor material and forming a wall of the cavity.

7. The Schottky diode of claim 6, wherein the dielectric structure comprises a first dielectric layer forming a side wall of the cavity and a second dielectric layer on the first dielectric layer and forming the overhanging projection.

8. The Schottky diode of claim 7, wherein the dielectric structure comprises a third dielectric layer on the second dielectric layer and defining a tapered portion of the opening in the dielectric structure.

9. The Schottky diode of claim 1, further comprising a bonding pad disposed over and electrically connected to the metal material.

10. A method of forming a Schottky diode, comprising:
providing a semiconductor surface; and
forming a dielectric structure defining an opening to the semiconductor surface; and
forming a contact structure extending through the opening in the dielectric structure to form a Schottky barrier junction with the semiconductor surface, wherein at the semiconductor surface at least a portion of the Schottky barrier junction is spaced apart from the dielectric structure by a lateral distance of at least 200 nm.

11. The method diode of claim 10, wherein a cavity surrounds the Schottky barrier junction.

12. The method of claim 11, wherein the dielectric structure includes a projection overhanging the semiconductor surface and forming a wall of the cavity.

13. The method of claim 12, wherein the dielectric structure comprises a first dielectric layer forming a side wall of the cavity and a second dielectric layer on the first dielectric layer and forming the overhanging projection.

14. The method of claim 10, further comprising forming a bonding pad disposed over and electrically connected to the Schottky barrier junction.

15. A Schottky diode, comprising:
a semiconductor surface;
a dielectric structure defining an opening to the semiconductor surface; and
a contact structure extending through the opening in the dielectric structure to form a Schottky barrier junction with the semiconductor surface, wherein the contact structure comprises a bonding pad overlying the Schottky barrier junction and at least a portion of the dielectric structure and being electrically connected to the Schottky barrier junction.

16. The Schottky diode of claim 15, wherein the contact structure comprises a Schottky metal layer electrically connected to the bonding pad and forming the Schottky barrier junction with the semiconductor surface.

17. The Schottky diode of claim 15, wherein a top portion of the opening in the dielectric structure is tapered.

18. The Schottky diode of claim 15, wherein a bottom portion of the dielectric structure defines at least part of a cavity at the semiconductor surface adjacent to the Schottky barrier junction.

19. A method of forming a Schottky diode, comprising:
providing a semiconductor surface;
forming a dielectric structure defining an opening to the semiconductor surface; and
forming a contact structure extending through the opening in the dielectric structure to form a Schottky barrier junction with the semiconductor surface, wherein the contact structure comprises a bonding pad overlying the Schottky barrier junction and at least a portion of the dielectric structure and being electrically connected to the Schottky barrier junction.

20. The method of claim 19, wherein a bottom portion of the dielectric structure defines at least part of a cavity at the semiconductor surface adjacent to the Schottky barrier junction.
